(19) United States
(12) Patent Application Publication
(10) Pub. No.: US 2003/0107114 A1
(43) Pub. Date: Jun. 12, 2003

(54) Thermal circuitry

(76) Inventors: Yee Loy Lam, Singapore (SG); Kian Hin Victor Teo, Singapore (SG); Cher Liang Randall Cha, Singapore (SG); Theng Theng Goh, Singapore (SG)

Correspondence Address: BUCKLEY, MASCHOFF, TALWALKAR, & ALLISON, 5 ELM STREET, NEW CANAAN, CT, 06840, US

(21) Appl. No.: 10/266,555

(22) Filed: Oct. 8, 2002

(30) Foreign Application Priority Data
Oct. 9, 2001 (GB) 0124220.5

(51) Int. Cl. H01L 23/495

(52) U.S. Cl. 257/675

(57) ABSTRACT

In the present invention, an assembly comprises one or more semiconductor optoelectronic devices sandwiched between two substrates with thermal circuitry so to provide a route by which heat can be transported from both the n-side and p-side of the semiconductor device to a cooling element. The arrangement proposed is robust, benefiting from the stability and flexibility of component integration provide by simultaneous n and p-side down configuration. The arrangement also allows a large thermal gradient to be achieved with respect to the active region of an optoelectronic device from both the n-side and p-side, resulting in fast and efficient heat spreading.

### FIELD OF THE INVENTION

The present invention relates to pathways for the conduction of heat from a semiconductor optoelectronic device.

### BACKGROUND TO THE INVENTION

During operation, many semiconductor optoelectronic devices generate substantial heat which not only raises the temperature of the device itself but, via radiative and conductive heat transfer, also raises the temperature of adjacent devices and substrates. Efficient heat dissipation requires a thin device substrate which is limited by fabrication constraints, therefore necessitating external heat removal mechanisms.

An example of such a device is a III-V semiconductor laser, where a temperature rise results in a change of the energy band-gap of the active medium and consequently an undesired shift in the laser wavelength. The semiconductor laser chip is often bonded to metallized regions on one side of a substrate. The substrate can act as an optical bench on which other components can be located. For this reason, silicon is often chosen as the substrate material due its low-cost, high mechanical strength, unique wet anisotropic etching characteristics and high thermal conductivity. The metallized regions provide the necessary electrical connections to power the semiconductor laser, and need to be electrically isolated from one another as well as from the semi-conducting silicon substrate. However, these electrical routes typically also transfer heat from the operating laser to the coupling bench by conduction and radiation, thereby heating it.

Thus there is a need to efficiently transfer the heat generated by a semiconductor device away from the active regions, in order that the device will function according to the intended design. The problem becomes more profound when multiple active regions are configured in close proximity in an integrated device. An example is a laser array where the total power can reach a level of several watts.

A common industry practice is to use techniques whereby one side of the semiconductor optoelectronic chip is attached to a cooling mechanism, to ensure that heat generated by the semiconductor device is efficiently transported away from the active regions. When the semiconductor device is arranged with the face containing the negative electrical connection attached to the cooling element, the arrangement is commonly referred to as the “n-side down” arrangement. Alternatively, the side of the semiconductor device in closer proximity to the active region may be attached to the cooling component. This arrangement is referred to as “p-side down” and offers greater thermal gradient in terms of proximity of the active region to the cooling element. In a generalized optoelectronic device where multi-patterned optical tracks are integrated to the semiconductor optoelectronic emitters, the p-side down configuration offers better thermal transportation. However, the n-side down approach offers better access to sections of the emitter and optical circuitry, which can allow superior device integration.

### SUMMARY OF THE INVENTION

According to the present invention, an assembly comprises one or more semiconductor optoelectronic devices sandwiched between two substrates with thermal circuitry so as to provide a route by which heat can be transported from both the n-side and p-side of a semiconductor optoelectronic device to a cooling element.

The thermal circuitry comprises heat conducting routings located on a suitable substrate and is arranged to provide a route for efficient heat transportation away from the active region of a semiconductor optoelectronic device to a cooling element, such as a heat sink or thermoelectric cooler.

As the thermal circuitry provides the preferential pathways for heat transport, it is preferred that the circuitry comprises materials with high thermal conductivity. Preferably, the thermal circuitry comprises a gold material.

Preferably, at least part of the thermal circuitry is in thermal contact with at least part of the semiconductor optoelectronic device. More preferably, at least part of the thermal circuitry is in thermal contact with a part of the semiconductor optoelectronic device such that a large thermal gradient is created with respect to the active region of said device.

The thermal circuitry will be in thermal contact with the optoelectronic device by means of heat conducting protrusions or pads on part of the thermal circuitry which contact corresponding pads or protrusions on said device. Typically, the protrusions will comprise solder bumps.

As the substrate hosting the thermal circuitry is typically in contact with a heat removing element, it is preferred that the substrate comprises a material with high thermal conductivity. Preferably, the material is characterized by a high mechanical strength for structural integrity and suitable etching characteristics for the addition or integration of optical devices. More preferably, the material is silicon based.

A plurality of optoelectronic components may be located on the substrate, some or all of which may be heat generating. The arrangement of components is typically determined prior to assembly, and therefore a thermal circuitry suitable for achieving optimal heat flow can be designed and implemented without compromising device functionality, not unlike in a well designed electrical circuit. Preferably, the dimensions and structure of the thermal circuitry is designed to optimize heat flow and heat spreading without compromising the operation of the said components.

At least part of the thermal circuitry may concurrently provide at least part of the route for delivering electrical power to the semiconductor optoelectronic device or devices. Therefore, it is preferred that at least part of the thermal circuitry comprises an electrically conducting material.

The arrangement proposed is robust, benefiting from the stability and flexibility of component integration provided by a simultaneous n and p-side down configuration. The arrangement also allows a large thermal gradient to be achieved with respect to the active region of an optoelectronic device from both the n-side and p-side, resulting in fast and efficient heat spreading.

In such an assembly it is necessary that the two substrates are connected in some manner to provide structural integrity to t/he assembled device. Furthermore, the two substrates should be accurately spaced apart such that good electrical contact is achieved between the optoelectronic device and electrical contact pads on the two substrates. This will typically be achieved by means of protrusions, such as solder bumps, from one or both substrates which attach to the opposing substrate at the correct spacing.

Preferably, the protrusions comprise a thermally conducting material so as to act as thermal interconnects which thermally contact the two substrates. More preferably, the protrusions comprise a thermally conducting material which connect portions of thermal circuitry on the substrates, thereby forming a continuous thermal circuit between the two substrates.

In this manner only one substrate, the thermal backplate, need be in direct contact with a cooling device. Heat removed via the other substrate can reach the cooling device by means of the thermal interconnects. Consequently, the requirement for this second substrate to have high thermal conductivity can be relaxed, broadening the acceptable range of materials for this substrate. However, the complex network of heat conducting pathways which result, should be optimized for distributed heat flow.

Preferably, the thermal circuitry of the assembly, including the thermal interconnects, are designed to optimize heat flow and heat spreading without compromising the operation of one or more components in the assembly.

If the interconnects are electrically conducting, they may contact with electrical pads on the two substrates, thereby forming a complete electrical circuit by means of which electrical power could be delivered to the optoelectronic device from external electrical connections to only one substrate.

Preferably, therefore, at least one of the thermal interconnects is electrically conducting and contacts with a portion of the thermal circuitry on the two substrates that is also electrically conducting.

In such an assembly, the substrate not in contact with the cooling device can be used as an optical bench on which photonic lightwave circuits (PLC), including optical waveguides, can be located.

Preferably, the semiconductor optoelectronic device(s) is (are) mounted n-side down on the thermal backplate.

Preferably, the semiconductor optoelectronic device(s) is (are) mounted p-side down on the optical bench.

Thus the assembly described in the present invention provides a robust means, whereby semiconductor optoelectronic devices can be mounted so that heat is efficiently removed from both sides of the devices and transported, via thermal circuitry, to a common cooling device. Furthermore the assembly allows for the possibility of delivering electrical power to the optoelectronic devices via the thermal circuitry and also integrating further optical devices within the assembly.

When a large amount of heat is generated, by a high density of semiconductor optoelectronic devices for example, there needs to be a corresponding way to enhance the heat dissipation function of the substrate on which the devices are located. One solution is to increase the size and amount of thermal circuitry on the substrate, which may not be possible without increasing the substrate area. This would lead to a bulkier device and increased costs for the additional substrate material. The problem could be ameliorated if instead, heat was transported from the side of the substrate close to the heat source to the opposing side, without excessive additional thermal circuitry.

Therefore, in a further variant of the thermal circuitry, the present invention provides a means for thermally connecting the two sides of a substrate comprising a through-substrate thermal via.

The interconnecting via can realized by standard etching techniques, such as wet etching of a suitable substrate material. The void created can be lined or filled with a material of high thermal conductivity to complete the via. As the preferred materials will typically also be electrically conducting, it may be necessary to electrically isolate the via material from the substrate, for instance if it is semiconducting. In this case a layer of a dielectric material can be deposited prior to adding the thermally conducting via material.

Preferably, the thermal via is located in a position where substantial heat is generated. More preferably, the via is located above an optoelectronic device in a position that is substantially centered on the heat generating active region of said device.

The shape of the via may be selected from a range of solid or annular forms, but will typically depend upon the etching properties and crystallographic structure of the substrate material. If the shape of the via is to be such that heat is spread uniformly over a wider area as it propagates through the via, then preferably the shape is a solid or annular frustum. Such shapes can be realized through the wet etching of silicon for instance. However, a dry etching process permits the fabrication of straight vias with a uniform cross-sectional area. Such vias are preferable when a higher packing density and therefore a higher level of device integration is desired.

Of course, there may be many such through substrate vias conducting heat away from a plurality of sources. Once heat has been conducted to the other side the substrate, by means of the thermal via, it can be removed immediately if the substrate is directly contacted to a cooling device. Otherwise, the large unused area on this side of the substrate provides an extensive base for the location of thermal circuitry which can transport heat from the via to a cooling device. Furthermore, by the use of additional vias heat can be conducted from said circuitry back through the substrate to the side hosting the heat sources, but at a chosen location.

The use of such vias in a thermally-connected two substrate assembly, according to one aspect of the present invention, provides an alternative route for transporting heat from the optical bench substrate to the thermal backplate substrate. Heat, from a source located on the optical bench, can be conducted through the substrate, along a thermal circuit and back through the substrate at the location of a thermal interconnect, and thence to the thermal backplate.

Of course, further variants of this design are possible, including the use of thermal vias to conduct heat through the thermal backplate, thereby relaxing the thermal conductivity requirements for the substrate.

Thus a combination of thermal circuitry, interconnects and vias provides the means for constructing compact optical devices, comprising a high density of heat-generating sources, with a robust mechanism for good thermal management.

### BRIEF DESCRIPTION OF THE DRAWINGS

Examples of the present invention will now be described in detail with reference to the accompanying drawings, in which:

FIG. 1 is a perspective view of the components of an optical mount with thermal circuitry, in accordance with the present invention;

FIG. 2 is an end view of the assembled optical mount of FIG. 1, also showing a cooling element;

FIG. 3 indicates the direction of heat flow in FIG. 2;

FIG. 4 is a side view of an optical mount with thermal vias, in accordance with the present invention; and,

FIG. 5 shows a perspective view of an example of a thermal via.

### DETAILED DESCRIPTION

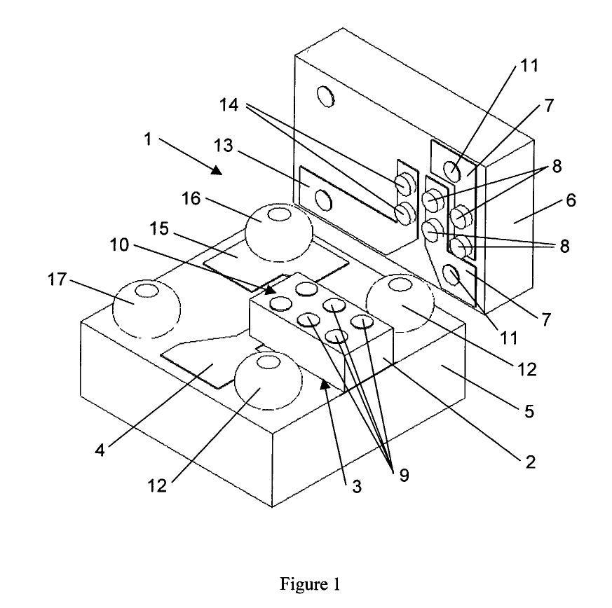

FIG. 1 shows the two parts of an optical device 1 designed to house a semiconductor laser chip 2. The laser chip 2 is mounted with its n side 3 down on an electrical routing pattern 4 located on a substrate 5, which acts as a thermal backplate and which is typically mounted on a cooling device such as a thermoelectric cooler. The substrate 6 features thermal routings or circuitry 7, comprising gold foil, on which are located small solder bumps 8 that contact corresponding pads 9 on the p side 10 of the laser chip 2. The thermal routings 7 also have larger pads 11 which contact thermal interconnects 12, completing a thermal circuit by means of which heat is conducted to the thermal backplate 5.

Substrate 6 also features an electrical routing pattern 13 which contacts the p side 10 of the laser chip 2 by means of small solder bumps 14. Electrical routing pattern 13 is also in contact with an electrical routing pattern 15 on the thermal backplate 5 by means of an electrical interconnect 16. Together with a stand alone thermal interconnect 17, the thermal interconnects 12 and electrical interconnect 16 give the assembled mount structural integrity and also accurately space the two substrates 5 and 6 such that the thermal 7 and electrical 13 routing patterns are in good contact with the p side 10 of the laser chip 2. These interconnects will typically comprise solder bumps.

Thus the assembled optical device provides a compact and simple way of removing heat from both sides of a semiconductor optoelectronic device, such as a laser chip, and transporting it to a common substrate and thence to a cooling device. In this embodiment, the optoelectronic device can also be supplied electrical power by connections to electrical routing patterns on the thermal backplate.

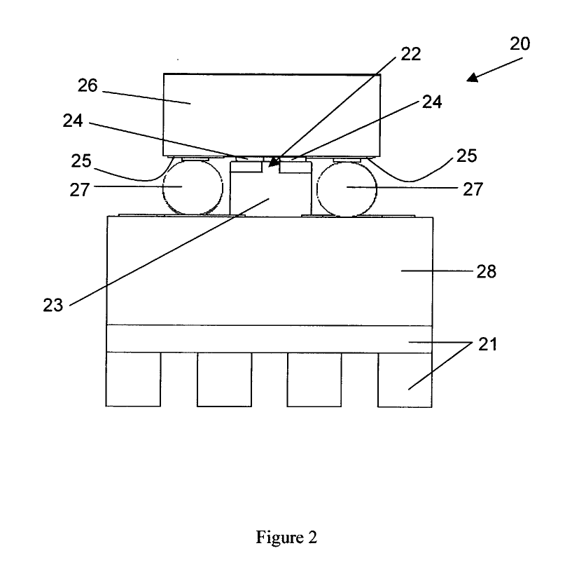

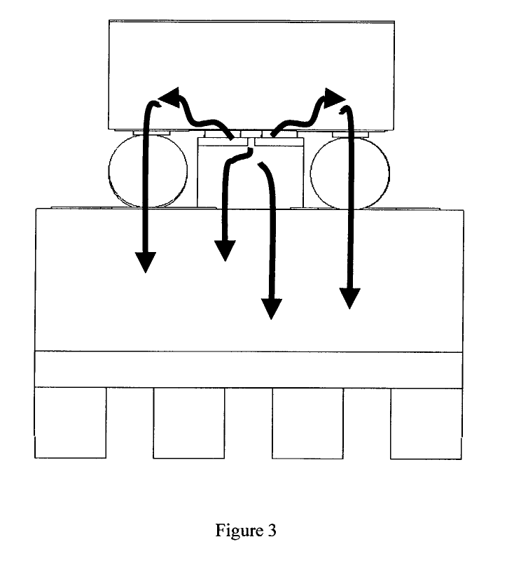

FIG. 2 shows an end view of the assembled optical device 20 of FIG. 1, and also its location on a cooling element or heat sink 21. Heat is conducted from the active region 22 of the optoelectronic device 23 via solder bumps 24 and thermal routings 25 on the substrate 26 to the thermal interconnects 27 and thence via the thermal backplate 28 to the cooling element 21. The intended routes for the flow of thermal energy is shown in FIG. 3.

The use of through substrate thermal vias has the potential to reduce the amount of thermal circuitry required on the side of a substrate in contact with a semiconductor optoelectronic device. This is of particular interest where space is at a premium, or where an increase in substrate material would be prohibitively expensive.

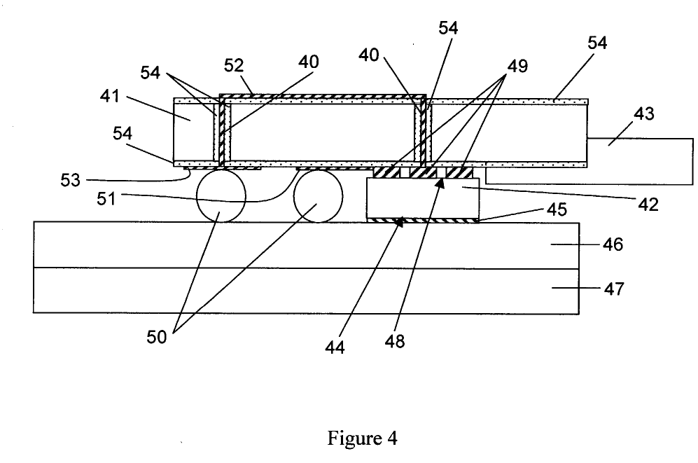

FIG. 4 shows a variant of the optical device shown in FIGS. 1 to 3, in which through substrate thermal vias 40 are used to transport heat from one side of a silicon substrate 41 to the other side. In this case the substrate 41 forms the basis of a silicon coupling bench whereby light is coupled from a semiconductor optoelectronic device 42 to an optical fibre 43. Heat is removed from the n side 44 of the optoelectronic device 42 by means of a metal pad 45 to the thermal backplate 46 and thence to a thermoelectric cooling device 47. Heat from the p side 48 of the optoelectronic device 42 is dissipated by means of thermal pads 49 and thence to thermal interconnects 50 by means of a direct thermal routing 51 or by means of a combination of through-substrate thermal vias 40 and thermal routings 52 and 53. As the thermal circuitry, including the vias, typically comprise a material with significant electrical conductivity, it is necessary to electrically insulate them from the semiconducting silicon by a layer of dielectric material 54, such as SiO₂. This isolation layer can be produced by thermal oxidation of silicon or chemical vapor deposition.

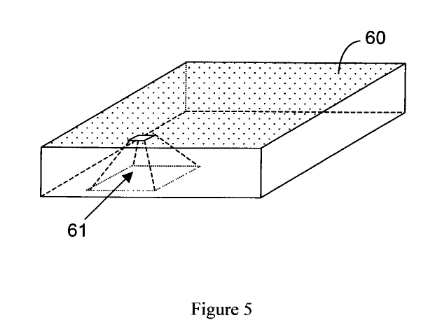

The commonly used techniques for creating through-substrate vias are wet chemical etching and dry etching. The former is widely used with silicon substrates, taking advantage of the unique properties of silicon, whereby the (111) crystal plane displays a very high wet etch selectivity (˜10⁴) over a presented (100) plane. FIG. 5 shows an example of the wet chemical etching of a silicon substrate 60, which results in a frusto-pyramidal feature 61. Metal can then deposited into the void created by the etching process and patterned to form contact pads. Such via openings occupy a large surface area, which reduces the packing density that can be achieved and therefore limits the level of potential device integration.

A higher packing density can be achieved by the use of straight vias, which requires the via to have a uniform cross-sectional area along its length. This can be achieved by a dry etching process, applied to silicon for example. However, etching such a via needs careful consideration of the etch mask, the etch gas chemistry and the aspect ratio of the desired via.

Thus the use of a through-substrate thermal via provides a simple means for removing heat from an optoelectronic device when substrate space is at a premium. The via allows heat to be transferred to the opposite side of the substrate where further thermal circuitry can be located. Although the examples given concentrate on silicon substrates, the idea of through-substrate thermal via interconnections can be applied to other substrate materials. Indeed, the use of thermal vias in the thermal management process relaxes the requirement for high thermal conductivity, thereby widening the potential range of materials that can be used for optical coupling benches.

1. An optoelectronic device disposed between a first and second substrate, each of the first and second substrate including thermal circuitry, for the conduction of heat from the optoelectronic device to a heat removing device, the thermal circuitry comprising a heat conductive pathway located on or in the first and second substrate, at least a portion of said thermal circuitry being in thermal contact with the optoelectronic device.

2. A device according to claim 1, in which the optoelectronic device is mounted p-side down on the first substrate, wherein a heat generating region of the optoelectronic device is in close proximity to the thermal circuitry, the first subtrate being located on a heat removing device so that at least a portion of the thermal circuitry is in thermal contact with the heat removing device.

3. A device according to claim 1 or 2, in which at least a part of the heat conductive pathway is electrically conductive.

4. A device according to any of claims 1 to 3, in which the heat conductive pathway comprises a patterned layer of thermally conductive material on a surface of at least one of the first and second substrates.

5. A device according to any of claims 1 to 3, in which the heat conductive pathway comprises a through substrate thermal via, the via comprising a void in the substrate filled at least in part with a thermally conductive material.

6. A device according to claim 5, in which the thermal via is substantially frusto-conical or frusto-pyramidal in shape.

7. A device according to claim 5 or 6, in which the void for the thermal via is fabricated by etching the substrate.

8. A device according to any of claims 5 to 7, in which the thermal via is in thermal contact with a heat conductive pathway on an upper and/or a lower surface of a substrate.

9. A device according to claims 4 to 8, in which the thermally conductive material is a metal.

10. A device according to claim 9, in which the metal is gold or a gold alloy.

11. A device according to any preceding claim, further comprising a thermal interconnect for connecting a portion of the thermal circuitry on or in the first substrate to a portion of the thermal circuitry on or in the second substrate.

12. A device according to any preceding claim, in which the thermal interconnect comprises a metallic protrusion for spacing the first substrate from the second substrate.

13. A device according to any preceding claim, wherein heat is preferentially conducted away from a heat generating region of the optoelectronic device by thermal circuitry in close proximity to said heat generating region.

14. A device according to claim 14, wherein heat is preferentially conducted via a thermal interconnect to thermal circuitry located on the other of the first and second substrate.
